(19) United States
(12) Patent Application Publication
(10) Pub. No.: US 2021/0336104 A1
(43) Pub. Date: Oct. 28, 2021

(54) LIGHT SOURCE STRUCTURE, ELECTRONIC DEVICE AND MANUFACTURING METHOD OF LIGHT SOURCE STRUCTURE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Zhen WANG, Beijing (CN); Haiwei SUN, Beijing (CN); Jian SANG, Beijing (CN); Junjie MA, Beijing (CN); Shubai ZHANG, Beijing (CN); Zhonghua LI, Beijing (CN)

(21) Appl. No.: 16/320,163

(22) PCT Filed: May 11, 2018
(86) PCT No.: PCT/CN2018/086430

§ 371 Date: Jan. 24, 2019

(30) Foreign Application Priority Data
Aug. 31, 2017 (CN) 201710772974.5

(51) Int. Cl. H01L 33/62; H01L 27/15; H01L 33/48; H01L 33/00

(52) U.S. Cl. CPC H01L 33/62; H01L 27/156; H01L 2933/0066; H01L 33/005; H01L 33/486

(57) ABSTRACT

A light source structure, an electronic device and a manufacturing method of a light source structure are disclosed. The light source structure includes a light-emitting unit, a printed circuit board and a bonding layer. The light-emitting unit includes a substrate and at least one light-emitting element on the substrate. The printed circuit board includes a first surface, and the light-emitting unit is disposed on the first surface of the printed circuit board via the substrate. The bonding layer is disposed between the substrate and the first surface of the printed circuit board, and for adhesively bonding the substrate and the printed circuit board together.

The application claims priority to the Chinese patent application No. 201710772974.5, filed on Aug. 31, 2017, the entire disclosure of which is incorporated herein by reference as part of the present application.

### TECHNICAL FIELD

At least one embodiment of the present disclosure relates to a light source structure, an electronic device and a manufacturing method of a light source structure.

### BACKGROUND

A surface mount technology is usually a kind of circuit assemble technology to mount a surface mount device (e. g. a light-emitting device), with no pin or a pin with short length, onto a surface of a printed circuit board (PCB) or other surfaces, and to achieve assembly by methods such as welding or soldering (e. g. reflow soldering or dip soldering). Light source structures of some electronic devices (e. g. display devices) are usually assembled with the surface mount technology. With the rapid development of the display device industry, the requirement to the optical performance of display devices is increasing, and an assembling process for the light source structures may influence the performance of the light source structure.

### SUMMARY

At least one embodiment of the present disclosure provides a light source structure, and the light source structure comprises a light-emitting unit, a printed circuit board and a bonding layer. The light-emitting unit comprises a substrate and at least one light-emitting element on the substrate; the printed circuit board comprises a first surface, in which the light-emitting unit is disposed on the first surface of the printed circuit board via the substrate; and the bonding layer is disposed between the substrate and the first surface of the printed circuit board, and for adhesively bonding the substrate and the printed circuit board together.

For example, in the light source structure provided by an embodiment of the present disclosure, at least one groove is disposed on the printed circuit board in a region, which overlaps the substrate, of the printed circuit board; and the bonding layer is disposed in the at least one groove.

For example, in the light source structure provided by an embodiment of the present disclosure, a surface of the bonding layer facing toward the substrate is substantially flush with the first surface of the printed circuit board.

For example, in the light source structure provided by an embodiment of the present disclosure, the bonding layer is a double-sided adhesive tape.

For example, in the light source structure provided by an embodiment of the present disclosure, the substrate is provided with an electrode pin, the printed circuit board is provided with a contact point, and the electrode pin electrically connects the contact point.

For example, in the light source structure provided by an embodiment of the present disclosure, the electrode pin and the contact point are welded together.

For example, in the light source structure provided by an embodiment of the present disclosure, the printed circuit board is a flexible circuit board.

For example, in the light source structure provided by an embodiment of the present disclosure, the light-emitting element is a light-emitting diode device.

For example, in the light source structure provided by an embodiment of the present disclosure, a plane shape of the light source structure is a strip or a planar surface.

For example, in the light source structure provided by an embodiment of the present disclosure, the light-emitting diode device is a flip chip and is configured to allow an electrode of the light-emitting diode to electrically connect the substrate directly.

For example, in the light source structure provided by an embodiment of the present disclosure, the light-emitting element further comprises a fluorescent layer covering the light-emitting diode device and the substrate.

At least one embodiment of the present disclosure further provides an electronic device, and the electronic device comprises any one of the light source structure provided by at least one embodiment of the present disclosure.

For example, the electronic device provided by an embodiment of the present disclosure is a display device, and the light source structure is configured as a backlight of the display device.

At least one embodiment of the present disclosure further provides a manufacturing method of a light source structure, and the method comprises: providing a printed circuit board and a light-emitting unit, in which the printed circuit board comprises a first surface, and the light-emitting unit comprises a substrate and at least one light-emitting element on the substrate; providing a bonding layer at a position, which overlaps the substrate, of the first surface of the printed circuit board; providing the light-emitting unit on the printed circuit board via the substrate, and allowing the bonding layer to adhesively bond the substrate and the printed circuit board together; electrically connecting the light-emitting unit to the printed circuit board.

For example, the manufacturing method of the light source structure provided by an embodiment of the present disclosure further comprises: providing a groove at the position, which overlaps the substrate, of the printed circuit board; providing the bonding layer in the groove and allowing a surface of the bonding layer facing toward the substrate to be substantially flush with the first surface of the printed circuit board.

For example, in the manufacturing method of the light source structure provided by an embodiment of the present disclosure, the substrate comprises an electrode pin and the printed circuit board is provided with a contact point; and electrically connecting of the light-emitting unit to the printed circuit board comprises allowing the electrode pin and the contact point to be welded together.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic view of a light source structure;

FIG. 2 is a plane schematic view of a light source structure provided by an embodiment of the present disclosure;

FIG. 3A is a sectional view along I-I′ in FIG. 2;

FIG. 3B is another sectional view along I-I′ in FIG. 2;

FIG. 4 is a schematic view of an electronic device provided by an embodiment of the present disclosure;

FIGS. 5A-5F are schematic views of a manufacturing method of a light source structure provided by an embodiment of the present disclosure; and

FIGS. 6A-6B are schematic views of another manufacturing method of a light source structure provided by an embodiment of the present disclosure.

### REFERENCE NUMERAL

1′—substrate; 2′—light-emitting diode; 3′—fluorescent layer; 4′—printed circuit board; 5′—electrode pin; 6′—soldering tin; 7′—bonding adhesive; 1—substrate; 2—light-emitting element; 3—fluorescent layer; 4—printed circuit board; 401—first surface of the printed circuit board; 5—electrode pin; 6—solder; 7—bonding adhesive; 8—bonding layer; 9—groove; 10—light source structure; 11—light guide structure; 12—display panel; 13—reflective structure; 14—sealant; 15—light-emitting unit; 100—display device.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and so on are only used to indicate relative position relationship, and when the position of the object which is described is changed, the relative position relationship may be changed accordingly.

The drawings of the present disclosure are not strictly drawn in a real scale in size. Specific sizes of the structures may be determined according to practical needs. The number of a light-emitting element and the number of an electrode pin are not limited to the numbers as illustrated in the drawings. The drawings of the present disclosure are only schematically structural views.

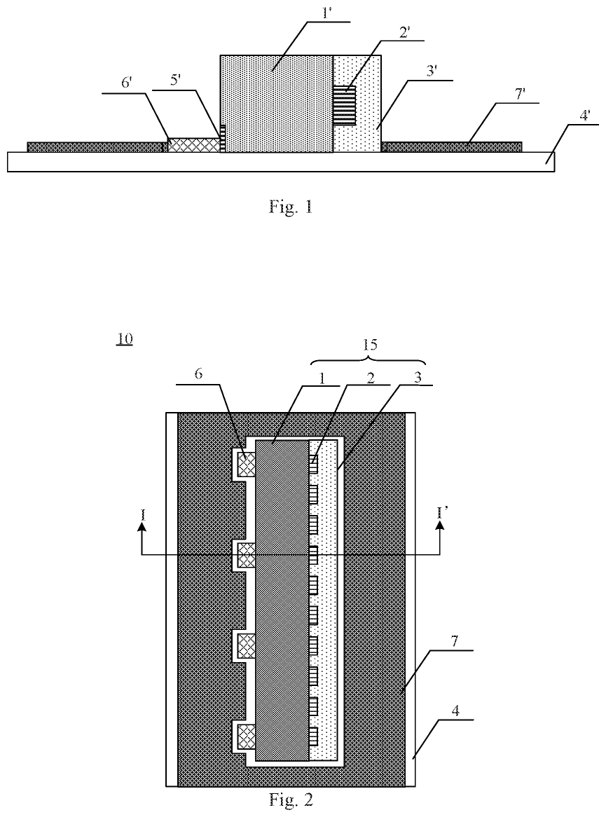

FIG. 1 is a schematic view of a light source structure. As illustrated in FIG. 1, the light source structure comprises a light-emitting device, a printed circuit board 4′ and a bonding adhesive 7′. The light-emitting device comprises a substrate 1′, and a light-emitting diode 2′ and a fluorescent layer 3′ which are on the substrate 1′, and the fluorescent layer 3′ covers the printed circuit board 4′. The light-emitting device is disposed on the printed circuit board 4′. The substrate 1′ is provided with an electrode pin 5′ onto a surface of the substrate and the printed circuit board 4′ is provided with a bonding pad onto a surface of the printed circuit board. The electrode pin 5′ and the bonding pad are welded together to realize an electrical connection between the electrode pin 5′ and the printed circuit board 4′, so as to realize an electrical connection between the light-emitting diode and the printed circuit board 4′. The light-emitting device further comprises a soldering tin 6′, and the soldering tin 6′ is used to connect the electrode pin 5′ and the bonding pad of the printed circuit board 4′ during the welding process (for example, soldering processes). Further, the bonding adhesive 7′ is provided onto the printed circuit board 4′, and the bonding adhesive 7′ is disposed around the light-emitting device, covers a portion of the printed circuit board, and is configured to adhesively bond the printed circuit board with an apparatus to be equipped with the light source structure, for example, the apparatus to be equipped with the light source structure may be a lighting device and a display device.

During the above welding process, a jig and fixture may be used to limit a movement of the substrate 1′ relative to the printed circuit board 4′. The jig and fixture may be referred to related technologies of related art and may be a clamping fixture capable of limiting the movement of the substrate 1′ relative to the printed circuit board 4′. However, because a gap exists between the substrate 1′ and the printed circuit board 4′, and the soldering tin 6′ is in a molten state during the welding process, the soldering tin 6′ in a molten state can easily flow into the gap between the substrate 1′ and the printed circuit board 4′. As a result, the soldering tin in the gap elevates the substrate 1′ at corresponding positions after the welding process is finished; this causes an inhomogeneous thickness of the light source structure and reduces a product yield of the light source structure. Moreover, this may cause difficulties in controlling the thickness of a device equipped with the light source structure. For example, if the thickness of a display device equipped with the light source structure is difficult to control, the produced display device has an inhomogeneous thickness and a yield of the product of the display device is adversely influenced.

Structures, methods and technical effects related to the present disclosure are described below in detail with reference to a plurality of specific embodiments.

At least one embodiment of the present disclosure provides a light source structure, and the light source structure comprises a light-emitting unit, a printed circuit board and a bonding adhesive. The light-emitting unit comprises a substrate and at least one light-emitting element on the substrate. The printed circuit board comprises a first surface, in which the light-emitting unit is disposed on the first surface of the printed circuit board via the substrate. The bonding layer is disposed between the substrate and the first surface of the printed circuit board, and for adhesively bonding the substrate and the printed circuit board together.

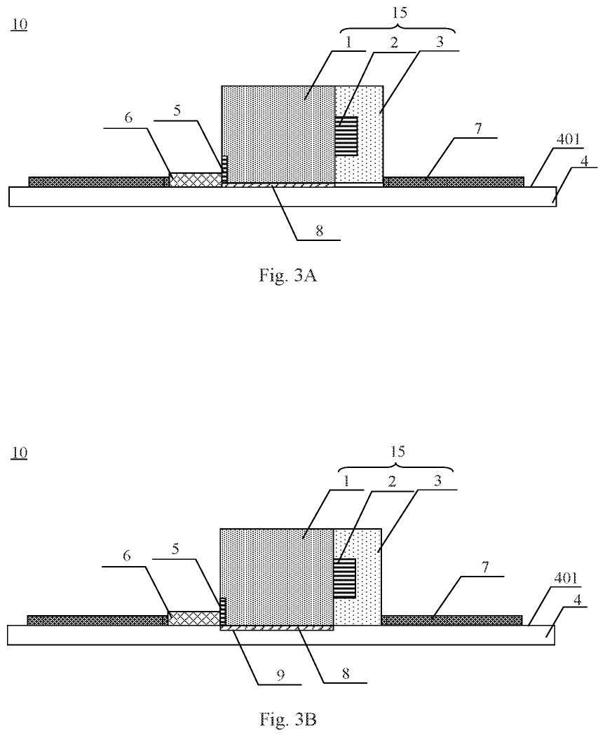

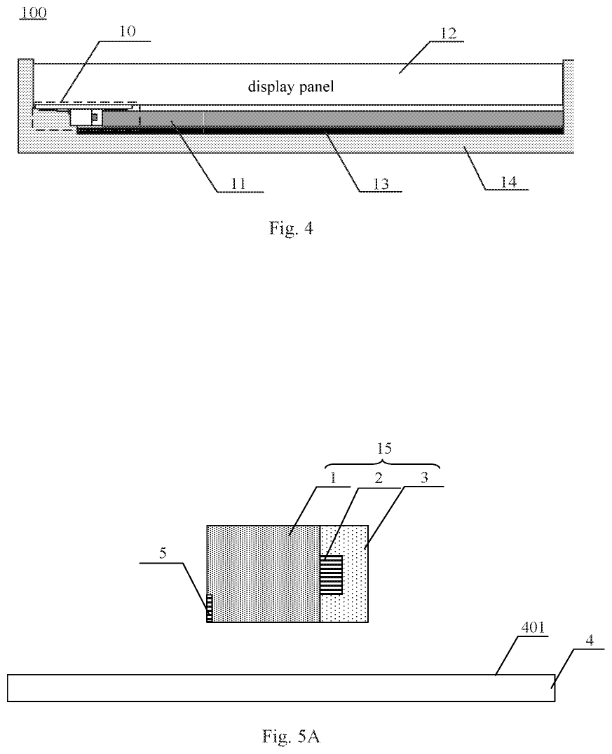

Exemplarily, FIG. 2 is a plane schematic view of a light source structure provided by an embodiment of the present disclosure, FIG. 3A is a sectional view along I-I′ in FIG. 2 and FIG. 3B is another sectional view along I-I′ in FIG. 2.

As illustrated in FIG. 2 and FIG. 3A, the light source structure comprises a light-emitting unit 15, and a printed circuit board 4 and a bonding layer 8. The light-emitting unit 15 comprises a substrate 1, and a plurality of light-emitting elements 2 on the substrate 1. The light-emitting elements 2 electrically connect the substrate 1. The printed circuit board 4 comprises a first surface 401, and the light-emitting unit 15 is disposed on the first surface 401 of the printed circuit board via the substrate 1, that is, the substrate 1 is fixed to the first surface 401. The bonding layer 8 is disposed between the substrate 1 and the first surface 401 of the printed circuit board, to adhesively bond the substrate 1 and the printed circuit board 4, so as to realize a fixation of the light-emitting unit 15 and the substrate 1. By this way, no gap exists between the substrate 1 and the printed circuit board 4, this can prevent foreign matters from being between the substrate 1 and the printed circuit board 4 during subsequent manufacturing processes and thus can avoid an inhomogeneous thickness of the light source structure at the overlap region of the substrate 1 and the printed circuit board 4.

It should be noted that one light-emitting unit may comprise one or more light-emitting elements. Plural light-emitting elements may be provided in one light-emitting unit in the embodiments of the present disclosure, specific number of the light-emitting elements may be designed according to practical needs of the product, and the number of the light-emitting elements is not limited to the number as illustrated in the embodiments of the present disclosure.

For example, the bonding layer 8 may be a double-sided adhesive tape capable of enduring a relatively high temperature during the welding process, for example, the bonding layer 8 may be a double-sided adhesive tape resistant to a high temperature. For example, the double-sided adhesive tape resistant to a high temperature may be a polyethylene terephthalate (PET) based high-temperature adhesive tape, a polyethylene (PE) based foam tape, a polyimide film tape, a polyvinyl chloride (PVC)-based double-sided adhesive tape, a Teflon based high-temperature adhesive tape or a high-temperature textured paper tape and so on. Temperature ranges that these double-sided adhesive tapes resistant to a high temperature can endure vary by materials of which these double-sided adhesive tapes are made. For example, the Teflon based high-temperature adhesive tape can endure a temperature up around 230° C., the PET based high-temperature adhesive tape can endure a temperature up around 200° C., and the polyimide film tape can endure a temperature up around 300° C. Of course, the bonding layer 8 is not limited to above-mentioned cases, and no specific limitations will be given to embodiments of the present disclosure in this respect.

For example, the substrate 1 is provided with an electrode pin 5, for example, onto a surface of the substrate 1, and the printed circuit board is provided with a contact point, for example, onto a surface of the printed circuit board. The electrode pin 5 electrically connects the contact point so as to realize an electrical connection between the light-emitting element 2 and the printed circuit board 4. For example, the printed circuit board 4 may be provided with a bonding pad, on which the contact point is provided.

For example, the electrode pin 5 and the contact point may be welded together (through reflow soldering, dip soldering or hand welding and so on). The electrode pin 5 and the contact point are welded together through a solder 6, so as to realize an electrical conduction between the electrode pin 5 and the contact point. For example, the solder 6 may be a tin solder, a silver solder, a cooper solder and so on. The tin solder comprises at least one of a pure tin, a tin lead an alloy solder, a tin solder with antimony, a tin solder with cadmium, a tin solder with cooper and so on. Of course, the solder 6 may be made of other materials which can achieve similar or same effects, and are not limited to the above-listed cases, and those skilled in the art can make a choice according to practical demands of products.

During the welding process, the solder 6 is in a molten state, and if a gap exists between the substrate 1 and the printed circuit board 4, the molten solder may flow into the gap between the substrate 1 and the printed circuit board 4, this may increase the thickness of the light source structure 10 at the position where the solder exists between the substrate 1 and the printed circuit board 4. This may cause an inhomogeneous thickness of the light source structure 10 and a difficulty in controlling the thickness of light source structure 10 in mass production, and thus a uniform thickness is difficult to be achieved, This reduces a yield of the product of the display device and further causes a difficulty in controlling a thickness of the device equipped with the light source structure. For example, the thickness of a display device equipped with the light source structure is difficult to control, this results an inhomogeneous thickness of the produced display device and an adverse influence on the yield of the product of the display device. However, in the light source structure provided in an embodiment of the present disclosure, because the substrate 1 and the printed circuit board 4 are adhesively bonded by the bonding layer 8, the gap between the substrate 1 and the printed circuit board 4 is eliminated or reduced, this helps to alleviate or avoid the above-mentioned problems during the welding process and to improve the yields of the light source structure and the device equipped with the light source structure. Besides, during the welding process, a jig and fixture is usually used to reduce the thickness of the gap between the substrate 1 and the printed circuit board 4; for example, the jig and fixture is used to press the substrate onto the first surface 401 of the printed circuit board as tightly as possible, and meanwhile to limit the movement of the substrate relative to the printed circuit board 4 so as to prevent the relative position of the substrate 1 and the printed circuit board 4 from changing. In an embodiment of the present disclosure, because the bonding layer 8 is used to adhesively bond the substrate 1 and the printed circuit board 4 together, the relative position of the substrate 1 and the printed circuit board 4 is fixed, the subsequent process is facilitated and the requirement to the jig and fixture is lowered.

For example, the light-emitting element 2 may be a light-emitting diode device, for example, a light-emitting diode or a light-emitting diode chip. Correspondingly, the light-emitting unit 15 may be a structure of light-emitting diode packaging. For example, the light-emitting element 2 may be a plurality of surface mounting light-emitting diodes (SMD LED), or a chip on board (COB) or light-emitting elements of other types. The chip may be a chip of inorganic light-emitting diode, inorganic laser diode, or organic light-emitting diode. It should be noted, in an embodiment of the present disclosure, the structure of light-emitting diode packaging may comprise one or more light-emitting diodes or light-emitting diode chips; that is, one light-emitting unit as mentioned above may comprise one or more light-emitting elements. Moreover, the number of the light-emitting unit is not limited to the number as illustrated in the embodiments of the present disclosure, and may be designed by those skilled in the art according to practical needs. The light-emitting element 2 and the light-emitting unit 5 which are illustrated above are exemplary examples, and the light-emitting element 2 and the light-emitting unit 5 are not limited to the above-listed cases.

For example, the above-mentioned light-emitting diode chip may be a flip chip, an electrode of which electrically connects the substrate 1 directly. A conventional light-emitting diode chip (an normal chip or a wire bonding chip) electrically connects the substrate 1 through a metal line, and the electrical surface of the conventional light-emitting diode chip is facing upward (i. e. facing away from the substrate); however, the electrical surface of the flip chip is facing downward (i. e. facing toward the substrate), this is equivalent to the case where the conventional light-emitting diode chip is turned upside down. For example, the flip-chip light-emitting diode does not need a metal line, that is, welding of a metal line and the substrate 1 is necessary. The flip-chip light-emitting diode is more stable than the wire bonding type light-emitting diode chip and avoids a poor bonding and an easy breakage problem of the metal line.

For example, the plane shape of the light source structure (i.e., the orthographic projection of the light source structure on the paper surface in FIG. 2) may be a strip or a planar surface, which may respectively satisfy requirements of serving as a strip light source and a surface light source in a display device or a light device. In the embodiment as illustrated in FIG. 2, the plane shape of the light source structure is a rectangle, and the plane shape of the light source structure may be other shapes in in other embodiments. The plane shape of the light source structure may be a regular shape or an irregular shape. The plane shape of the light source structure may be a round, an oval, a sector or irregular shapes and so on, and may be designed according to specific requirements of a device to be equipped with the light source structure.

For example, the printed circuit board 4 may adopt a rigid substrate or may be a flexible printed circuit board. For example, the flexible substrate may be a flexible printed circuit board adopting a polyimide film or a polyester film as the base material, and has characteristics such as a dense wiring arrangement capability, light weight, and good flexibility, which in favor of obtaining a flexible device based on the light source structure.

For example, in the embodiment as illustrated in FIG. 3A, the light-emitting element 2 is a light-emitting diode chip, and the light-emitting unit 15 further comprises a fluorescent layer 3 covering at least one light-emitting diode chip and the substrate 1. The type of phosphor powder which is used to fabricate the fluorescent layer 3 can be determined according to a wavelength band (light emission color) of the light to be emitted by the light-emitting diode chip, so as to allow the light-emitting unit 15 to emit desired light. For example, in the case where the light source structure is applied in display lighting, the fluorescent layer 3 may convert the light emitted by the light-emitting diode of the emitting diode chip into the light allowing human eyes to be comfortable. During practical applications, the wavelength of the light-emitting diode may be controlled through selecting a material for making the light-emitting diode and adopting a driving circuit to control a current running through the light-emitting diode. By this way, a light emission color may be controlled and thus light with various colors may be obtained. For example, the above-mentioned light source structure may be applied for a display board, an advertising board and so on.

For example, the first surface 401 of the printed circuit board is also provided with an adhesive 7, and the adhesive 7 is disposed around the light-emitting unit 15. For example, in FIG. 3A, the adhesive 7 surrounds the light-emitting unit 15 in a closed manner. However, in other embodiments of the present disclosure, the adhesive 7 may surround a portion of the light-emitting unit 15. The adhesive 7 covers at least a portion of the printed circuit board, for example, the adhesive 7 covers the printed circuit board 4 at a position close to an edge of the printed circuit board 4, and is used to adhesively bond the printed circuit board 4 and a device to be equipped with the light source structure together, and the device to be equipped with the light source structure is, for example, a lighting device, a display device and so on.

In another embodiment of present disclosure, at least one groove may be disposed on the printed circuit board in the region, which overlaps the substrate, of the printed circuit board, and the bonding layer is disposed in the at least one groove. For example, FIG. 3B illustrates another light source structure provided by another embodiment of the present disclosure, the embodiment as illustrated in FIG. 3B differs from the embodiment as illustrated in FIG. 3A in that a groove 9 is disposed on the printed circuit board 4 in an overlap region of the printed circuit board 4 and the substrate 1, and the bonding layer 8 is disposed in the groove 9. As illustrated in FIG. 2, the substrate 2 extends along a vertical direction (extends from an upper side to a lower side of FIG. 2), and the groove also extends in that direction. By this way, the substrate 1 may be prevented from being elevated by the bonding layer 8, and this may reduce the influence, of bonding layer 8, to the thickness of the light source structure in the welding process while solving the above-mentioned technical problem. This can help to obtain a light and thin light source structure and a light and thin product made with the light source structure.

For example, as illustrated in FIG. 3B, the surface of the bonding layer 8 facing toward the substrate 1 is substantially flush with (i.e., in the same plane with) the first surface 401 of the printed circuit board. By this way, after disposing the bonding layer 8, a flat surface can still be formed for the printed circuit board 4, this helps to adhesively bond the substrate 1 and the printed circuit board 4 together without increasing the thickness of the light source structure, and this also helps to reduce the thickness of the gap between the substrate 1 and the printed circuit board 4. For example, the gap between the substrate 1 and the inside wall of the groove can be avoided and thus the solder in molten can be prevented from entering into the gap during the above-mentioned welding process.

The light source structure provided by the embodiments of the present disclosure may be applied in a variety of electronic devices, such as a lighting device including a lighting device for daily life or a decorative lighting device, or a display device. For example, the light source structure may be the backlight for a display device.

At least one embodiment of the present disclosure further provides an electronic device, and the electronic device comprises any one of the light source structures provided by the embodiments of the present disclosure.

The electronic device may be a lighting device, and the lighting device comprises any one of the above-mentioned light source structures. The lighting device may emit a monochromatic light, such as white light, red light, green light or blue light, and may also emit a polychromatic light, such as light, with different colors, obtained by a RGB color scheme (that is, through mixing light with red, green and blue color). The lighting device may be a lamp, a display board, an advertising board and so on.

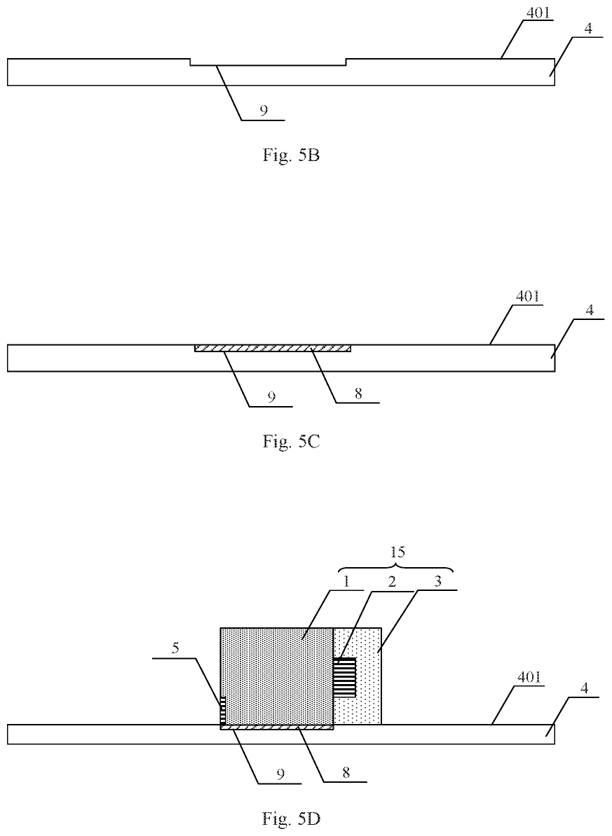

For example, the electronic device may also be a display device. FIG. 4 is a schematic view of an electronic device provided by an embodiment of the present disclosure. As illustrated in FIG. 4, for example, the light source structure 10 may be configured as a component of a backlight for a display device 100, for example, the light source structure 10 may be a side entry backlight disposed at a side of a display panel 12. The light source structure 10 is configured to emit light in the way where the light is able to be incident into the display panel 12. Of course, the light source structure 10 may also be a straight down backlight.

For example, the display device 100 may further comprise a light guide structure 11, which is configured to allow the light emitted by the light source structure 10 to be able to be incident into the display panel via the light guide plate with better effect. This helps to increase light utilization.

For example, the display device 100 may further comprise a reflective structure 13, and the reflective structure 13 is configured to allow partial light emitted by the light source structure 10 or/and light outputted from the light guide structure 11 to change a transmission direction after the above-mentioned light is reflected by the reflective structure 13, so that more light may be incident into the display panel 12 and thus light utilization is increased.

For example, the display device 100 may further comprise a sealant 14 partially around the display panel 12, the light source structure 10 and the reflective structure 13, and is configured to adhesively bond, fix and protect various components of the display device 100.

For example, the display device provided by the embodiments of the present disclosure may be a liquid crystal display device or other display devices equipped with a backlight.

It should be noted that, FIG. 4 only illustrates components, which are directly relative to the light source structure, of the display device 100, and those skilled in the art may refer to related technologies to provide other structures of the display device 100. The structures as illustrated in FIG. 4 are only examples, and the shapes and the relative positions of the components of the display panel 100 are not limited to the case as illustrated in the figure.

At least one embodiment of the present disclosure further provides a manufacturing method of a light source structure, and the method comprises: providing a printed circuit board and a light-emitting unit. The printed circuit board comprises a first surface, and the light-emitting unit comprises a substrate and at least one light-emitting element on the substrate. The method further comprises: providing a bonding layer at a position, which overlaps the substrate, of the first surface of the printed circuit board; providing the light-emitting unit on the printed circuit board by means of (i.e., via) the substrate, allowing the bonding layer to adhesively bond the substrate and the printed circuit board together; and electrically connecting the light-emitting unit to the printed circuit board.

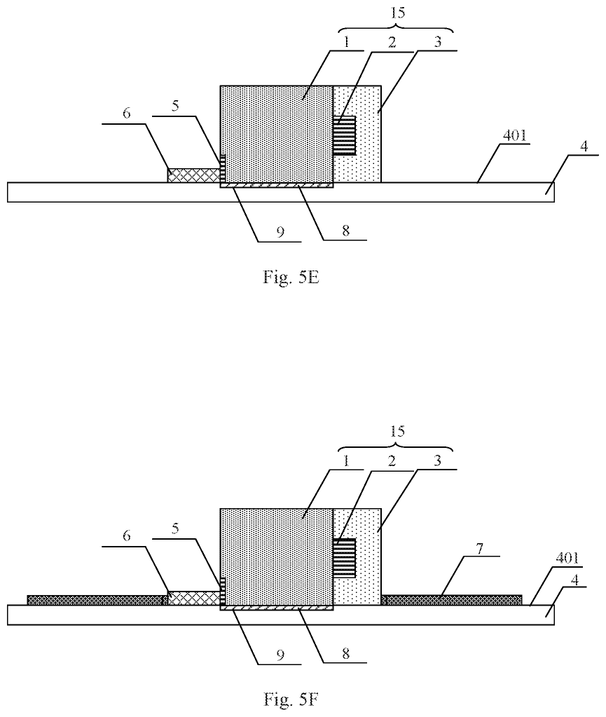

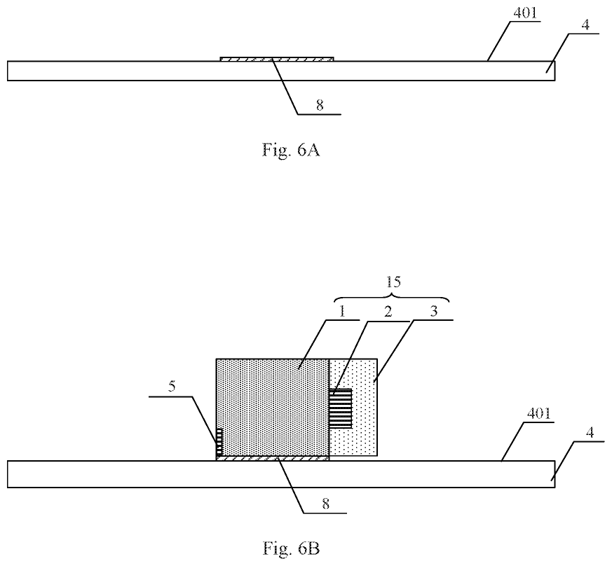

Exemplarily, FIGS. 5A-5F are schematic views of a manufacturing method of light source structure provided by an embodiment of the present disclosure, and FIGS. 6A-6F are schematic views of another manufacturing method of light source structure provided by an embodiment of the present disclosure.

Exemplarily, as illustrated in FIG. 5A, a printed circuit board 4 and a light-emitting unit 15 are provided. The printed circuit board 4 comprises a first surface 401, and may be a circuit board based on metal (such as a circuit board adopting an aluminum substrate, a copper substrate, a ferrum substrate), a ceramic circuit board or a flexible circuit board (adopting a polyimide film or a polyester film as the base material), and so on. The light-emitting unit 15 comprises a substrate 1 and at least one light-emitting element 2 on the substrate 1, and the light-emitting element electrically connects the substrate 1. The light-emitting element 2 may be a light-emitting diode device. For example, in the embodiment as illustrated in FIG. 5A, the light-emitting element is a light-emitting diode chip, and the light-emitting unit 15 may be a structure of a light-emitting packaging correspondingly. The light-emitting unit 15 further comprises a fluorescent layer 3 covering the light-emitting diode chip and the substrate 1, and the fluorescent layer 3 allows the light-emitting unit 15 to emit desired light. The substrate 1 is further provided with an electrode pin 5, which is used to electrically connect the printed circuit board 4. The first surface 401 of the printed circuit board 4 is provided with a contact point, and the contact point and the electrode pin 5 of the light-emitting unit 15 are welded together in subsequent processes.

The manufacturing method of the light source structure further comprises: providing a bonding layer at the position, which is to be overlapped with the substrate 1, of the first surface 401 of the printed circuit board 4. For example, as illustrated in FIG. 5B, a groove 9 may be disposed at the position, which is to be overlapped with the substrate 1, of the first surface 401 of the printed circuit board 4. For example, a photolithographic process or an exposure-development process may be employed to form the groove 9, and those skilled in the art may adopt suitable method to form the groove 9 according to the material of the printed circuit board 4.

As illustrated in FIG. 5C, the manufacturing method of the light source structure further comprises: disposing the bonding layer 8 in the groove 9, in which the bonding layer 8 is used to adhesively bond the substrate 1 and the printed circuit board 4 subsequently. Moreover, the surface of the bonding layer 8 facing toward the substrate is substantially flushed with the first surface 401 of the printed circuit board. By this way, the substrate 1 can be prevented from being elevated by the bonding layer 8 after providing the substrate 1, this can reduce an influence of the bonding layer 8 to the thickness of the light source structure and help to obtain a light and thin light source structure and a light and thin product made with the light source structure. The material of the bonding layer 8 may be referred to the descriptions in the first embodiment, and no further descriptions will be given here.

As illustrated in FIG. 5D, the light-emitting unit 15 is disposed on the printed circuit board 4 and the substrate 1 is adhesively bonded with the printed circuit board 4 through the bonding layer 8, that is, the light-emitting unit 15 is disposed on the printed circuit board via the substrate 1.

The manufacturing method of the light source structure further comprises electrically connecting the light-emitting unit 15 to the printed circuit board 4. For example, as illustrated in FIG. 5E, electrically connecting of the light-emitting unit 15 to the printed circuit board 4 comprises: welding the electrode pin 5 with the contact point. A solder 6 may be used to connect the electrode pin 5 with the contact point so as to realize an electrical connection between the electrode pin 5 and the contact point. The material of the solder 6 may be referred to the descriptions in the first embodiment. In the manufacturing method of the light source structure provided by the embodiments of the present disclosure, because the bonding layer 8 is used to adhesively bond the substrate 1 and the printed circuit board 4 together, the gap between the substrate 1 and the printed circuit board 4 is eliminated or the thickness of the gap is reduced, this helps to prevent the solder 6 in molten state from flowing into the gap between the substrate 1 and the printed circuit board 4 during the above-mentioned welding process, so as to eliminate or avoid an inhomogeneous thickness of the light source structure caused by an increased thickness of the light source structure 10 at the position where the solder exists between the substrate 1 and the printed circuit board 4, and this is in favor of improving a yield of the light source structure and the device equipped with the light source structure. Besides, during the welding process, a jig and fixture is usually used to reduce the gap between the substrate 1 and the printed circuit board 4; for example, the jig and fixture is used to press the substrate on the first surface 401 of the printed circuit board as tightly as possible, so as to limit the movement of the substrate relative to the printed circuit board 4, and to prevent the relative position of the substrate 1 and the printed circuit board 4 from changing. In the embodiments of the present disclosure, because the bonding layer 8 is used to adhesively bond the substrate 1 and the printed circuit board 4 together, the relative position of the substrate 1 and the printed circuit board 4 may be fixed, the requirement to the jig and fixture is lowered.

For example, as illustrated in FIG. 5F, the manufacturing method of the light source structure further comprises: providing an adhesive 7 onto the first surface 401 of the printed circuit board. The adhesive 7 is disposed around the light-emitting element 2, for example, partially or fully around the light-emitting element 2. The adhesive 7 covers at least a portion of the printed circuit board, for example, covering the printed circuit board at a position close to an edge of the printed circuit board 4, and the adhesive 7 is used to adhesively bond the printed circuit board 4 and a device to be equipped with the light source structure together, such as a lighting device, a display device and so on.

FIGS. 6A-6F are schematic views of another manufacturing method of light source structure provided by an embodiment of the present disclosure. The manufacturing method comprises: providing a printed circuit board 4 and a light-emitting unit 15, in which this process may be the same as what is illustrated in FIG. 5A, and may be referred to the above descriptions. The another manufacturing method differs from the embodiment as illustrated in FIGS. 5A-5F in that the bonding layer 8 may be directly disposed on the printed circuit board 4, as illustrated in FIG. 6A. As illustrated in FIG. 6B, the light-emitting unit 15 is disposed on the printed circuit board 4, and the substrate 1 is adhesively bonded with the printed circuit board 4 through the bonding layer 8. Other processes are the same as the embodiment as illustrated in FIGS. 5A-5F, and may be referred to the above descriptions. This method may achieved same or similar advantages as the embodiment as illustrated in FIGS. 5A-5F.

The light source structure manufactured by this method may be applied in a variety of electronic devices, such as a lighting device comprising a lighting device for daily life or decorative lighting device, or a display device, and the light source structure may be a backlight for a display device for example.

What are described above is related to the illustrative embodiments of the disclosure only and not limitative to the scope of the disclosure; the scopes of the disclosure are defined by the accompanying claims.

1. A light source structure, comprising:
a light-emitting unit comprising a substrate and at least one light-emitting element on the substrate;
a printed circuit board comprising a first surface, wherein the light-emitting unit is on the first surface of the printed circuit board via the substrate; and
a bonding layer between the substrate and the first surface of the printed circuit board, and for adhesively bonding the substrate and the printed circuit board together.

2. The light source structure according to claim 1, wherein at least one groove is on the printed circuit board in a region, which overlaps the substrate, of the printed circuit board; and
the bonding layer is in the at least one groove.

3. The light source structure according to claim 2, wherein a surface of the bonding layer facing toward the substrate is substantially flush with the first surface of the printed circuit board.

4. The light source structure according to claim 1, wherein the bonding layer is a double-sided adhesive tape.

5. The light source structure according to claim 1, wherein the substrate is provided with an electrode pin, the printed circuit board is provided with a contact point, and the electrode pin electrically connects the contact point.

6. The light source structure according to claim 5, wherein the electrode pin and the contact point are welded together.

7. The light source structure according to claim 1, wherein the printed circuit board is a flexible circuit board.

8. The light source structure according to claim 1, wherein the light-emitting element is a light-emitting diode device.

9. The light source structure according to claim 1, wherein a plane shape of the light source structure is a strip or a planar surface.

10. The light source structure according to claim 8, wherein the light-emitting diode device is a flip chip and is configured to allow an electrode of the light-emitting diode to electrically connect the substrate directly.

11. The light source structure according to claim 8, wherein the light-emitting element further comprises a fluorescent layer covering the light-emitting diode device and the substrate.

12. An electronic device, comprising the light source structure according to claim 1.

13. The electronic device according to claim 12, wherein the electronic device is a display device and the light source structure is configured as a component of a backlight of the display device.

14. A manufacturing method of a light source structure, comprising:
providing a printed circuit board and a light-emitting unit, wherein the printed circuit board comprises a first surface, and the light-emitting unit comprises a substrate and at least one light-emitting element on the substrate;
providing a bonding layer at a position, which overlaps the substrate, of the first surface of the printed circuit board;
providing the light-emitting unit on the printed circuit board via the substrate, and allowing the bonding layer to adhesively bond the substrate and the printed circuit board together; and
electrically connecting the light-emitting unit to the printed circuit board.

15. The manufacturing method according to claim 14, further comprising:
providing a groove at the position, which overlaps the substrate, of the first surface of the printed circuit board; and
providing the bonding layer in the groove and allowing a surface of the bonding layer facing toward the substrate to be substantially flush with the first surface of the printed circuit board.

16. The manufacturing method according to claim 14, wherein the substrate comprises an electrode pin and the printed circuit board is provided with a contact point; and
electrically connecting of the light-emitting unit to the printed circuit board comprises allowing the electrode pin and the contact point to be welded together.

17. The light source structure according to claim 2, wherein the substrate is provided with an electrode pin, the printed circuit board is provided with a contact point, and the electrode pin electrically connects the contact point.

18. The light source structure according to claim 17, wherein the electrode pin and the contact point are welded together.

19. The light source structure according to claim 17, wherein the light-emitting element is a light-emitting diode device.

20. The light source structure according to claim 19, wherein the substrate comprises the electrode pin; and
the light-emitting diode device is a flip chip and is configured to allow an electrode of the light-emitting diode to electrically connect the electrode pin of the substrate.
